(19) United States
(12) Patent Application Publication
(10) Pub. No.: US 2014/0143289 A1
(43) Pub. Date: May 22, 2014

(54) Constrained System Endec

(71) Applicant: LSI CORPORATION, San Jose, CA (US)

(72) Inventors: Razmik Karabed, San Jose, CA (US); Shaohua Yang, San Jose, CA (US); Wu Chang, Sunnyvale, CA (US); Victor Krachkovsky, Allentown, PA (US); Zhiwei Wu, Shanghai (CN)

(73) Assignee: LSI Corporation, San Jose, CA (US)

(21) Appl. No.: 13/873,224

(22) Filed: Apr. 30, 2013

Related U.S. Application Data
(60) Provisional application No. 61/728,798, filed on Nov. 20, 2012.

(51) Int. Cl. H03M 7/30

(52) U.S. Cl. CPC H03M 7/30
USPC 708/203

(57) ABSTRACT

Various embodiments of the present invention provide apparatuses and methods for encoding and decoding data for constrained systems with reduced or eliminated need for hardware and time intensive arithmetic operations such as multiplication and division.

### CROSS REFERENCE TO RELATED APPLICATIONS

The present application claims priority to (is a non-provisional of) U.S. Pat. App. No. 61/728,798, entitled “Constrained System Endec”, and filed Nov. 20, 2012 by Karabed et al, the entirety of which is incorporated herein by reference for all purposes.

### BACKGROUND

Various products including hard disk drives and transmission systems utilize a read channel device to encode data, store or transmit the encoded data on a medium, retrieve the encoded data from the medium and decode and convert the information to a digital data format. Such read channel devices may include data processing circuits including encoder and decoder circuits or endecs to encode and decode data as it is stored and retrieved from a medium or transmitted through a data channel, in order to reduce the likelihood of errors in the retrieved data. It is important that the read channel devices be able to rapidly and accurately decode the original stored data patterns in retrieved or received data samples.

The encoded data may be constrained to follow one or more rules that reduce the chance of errors. For example, when storing data on a hard disk drive, it may be beneficial to avoid long runs of consecutive transitions, or long runs of 0's or 1's. As the amount of information to be stored or transmitted increases, designing endecs to encode data according to such constraints becomes increasingly difficult and can require complex circuitry using multiplier and divider circuits.

### BRIEF SUMMARY

Various embodiments of the present invention provide apparatuses and methods for encoding and decoding data for constrained systems with reduced or eliminated need for hardware and time intensive arithmetic operations such as multiplication and division. In some embodiments, this includes generating a directed graph or digraph DG that characterizes the constraint set for a constrained system, having an approximate eigenvector AE. In order to alleviate the complexity associated with implementation of arithmetic multiplications and divisions for large integers, a representation to a subset of digraph DG is identified that supports codes for which multiplication and division operations take place on integers that are powers of 2. This allows an encoder and a decoder, or an endec, to use much simpler binary shift operations rather than the more complicated multiplication and division operations.

In some embodiments, this includes generating an approximation AE* to the approximate eigenvector AE, such that the number of 1's in the binary representations of AE* coordinates does not exceed a number K. In a stage 1 state splitting operation, digraph DG is split using AE* to generate digraph DG1 with approximate eigenvector AE1 having at most K times as many states as digraph DG, where the weight or coordinate of each state in digraph DG1 is a power of 2. A second stage of state splitting is then performed on digraph DG1 using AE1, yielding a digraph DG2 with approximate eigenvector AE2 having only weights 0 and 1. The encoder/decoder then generated based on digraph DG2 will use multiplication and division operations only on integers that are powers of 2, greatly simplifying the encoder/decoder.

This summary provides only a general outline of some embodiments according to the present invention. Many other objects, features, advantages and other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals may be used throughout several drawings to refer to similar components. In the figures, like reference numerals are used throughout several figures to refer to similar components.

FIG. 1 depicts a data processing system in accordance with various embodiments of the present inventions;

FIG. 2 depicts a code generation system in accordance with some embodiments of the present inventions;

FIG. 3 depicts another code generation system in accordance with other embodiments of the present inventions;

FIG. 4 depicts a storage system including a multiplication and division free encoder and decoder in accordance with some embodiments of the present inventions;

FIG. 5 depicts a data processing system relying on multiplication and division free coding in accordance with various embodiments of the present inventions;

FIG. 6 depicts a digraph illustrating a constrained system in accordance with various embodiments of the present inventions;

FIGS. 7a and 7b depicts a digraph and corresponding 2^{nd} power digraph illustrating another constrained system in accordance with various embodiments of the present inventions;

FIG. 8 depicts state splitting of a state in a digraph in accordance with various embodiments of the present inventions;

FIG. 9 depicts a plot of latency of an encoder versus a P value used in generating the encoder in accordance with various embodiments of the present inventions; and

FIG. 10 depicts a flow diagram showing a method for generating a constrained systems endec in accordance with various embodiments of the present inventions.

### DETAILED DESCRIPTION OF THE INVENTION

Various embodiments of the present invention provide apparatuses and methods for encoding and decoding data for constrained systems with reduced or eliminated need for hardware and time intensive arithmetic operations such as multiplication and division. Reducing or eliminating multiplication and division in a constrained system encoder greatly simplifies the hardware design of the encoder and may be achieved with little or no increase in latency.

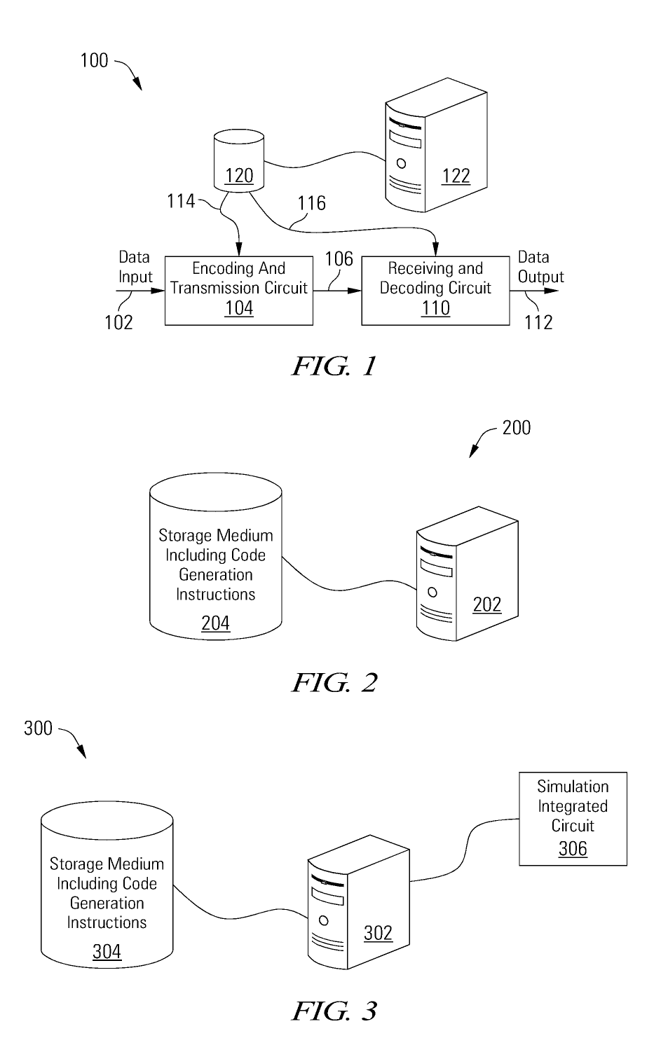

Turning to FIG. 1, a data processing system 100 is shown in accordance with various embodiments of the present inventions. Data processing system 100 includes a processor 122 that is communicably coupled to a computer readable medium 120. As used herein, the phrase “computer readable” medium is used in its broadest sense to mean any medium or media capable of holding information in such a way that it is accessible by a computer processor. Thus, a computer readable medium may be, but is not limited to, a magnetic disk drive, an optical disk drive, a random access memory, a read only memory, an electrically erasable read only memory, a flash memory, or the like. Based upon the disclosure provided herein, one of ordinary skill in the art will recognize a variety of computer readable mediums and/or combinations thereof that may be used in relation to different embodiments of the present inventions. Computer readable medium 120 includes instructions executed by processor 122 to produce a multiplication and division free constrained system encoder 114 and a corresponding decoder 116. The term “multiplication and division free” is used herein to an encoder in which at least some of the multiplication and division arithmetic operations are performed on integers that are powers of 2 and can therefore be performed using binary shift operations. The term “multiplication and division free” does not preclude the use of some traditional multipliers and dividers, if desired, in conjunction with the shift-based operations. Multiplication and division free constrained system encoder 114 is provided to an encoding and transmission circuit 104, for example as an encoder design to be used in the design of the encoding and transmission circuit 104 or as an executable encoder. The encoding and transmission circuit 104 encodes a data input 102 using multiplication and division free constrained system encoder 114 to produce a encoded data 106. The corresponding decoder 116 is provided to a receiving and decoding circuit 110 that decodes encoded data 106 using decoder 116 to provide a data output 112.

Turning to FIG. 2, a code generation system 200 is shown in accordance with some embodiments of the present invention. Code generation system 200 includes a computer 202 and a computer readable medium 204. Computer 202 may be any processor based device known in the art. Computer readable medium 204 may be any medium known in the art including, but not limited to, a random access memory, a hard disk drive, a tape drive, an optical storage device or any other device or combination of devices that is capable of storing data. Computer readable medium includes instructions executable by computer 202 to generate an multiplication and division free constrained system encoder and decoder. In some cases, the instructions may be software instructions. In other cases, the instructions may include a hardware design, or a combination of hardware design and software instructions. Based upon the disclosure provided herein, one of ordinary skill in the art will recognize other types of instructions that may be used in relation to different embodiments of the present inventions.

Turning to FIG. 3, another code generation system 300 is shown in accordance with other embodiments of the present invention. Code generation system 300 includes a computer 302 and a computer readable medium 304. Computer 302 may be any processor based device known in the art. Computer readable medium 304 may be any medium known in the art including, but not limited to, a random access memory, a hard disk drive, a tape drive, an optical storage device or any other device or combination of devices that is capable of storing data. Computer readable medium includes instructions executable by computer 302 to generate an multiplication and division free constrained system encoder and decoder. In some cases, the instructions may be software instructions. In other cases, the instructions may include a hardware design, or a combination of hardware design and software instructions. Based upon the disclosure provided herein, one of ordinary skill in the art will recognize other types of instructions that may be used in relation to different embodiments of the present inventions.

In addition, code generation system 300 includes a simulation integrated circuit 306. Simulation integration circuit 306 may be used to implement and test the multiplication and division free constrained system encoder and decoder, including encoding and decoding test data and providing data characterizing the performance of the encoder and decoder, such as incidence of error and latency information. Based upon the disclosure provided herein, one of ordinary skill in the art will appreciate a variety of distributions of work between computer 302 executing instructions and simulation integrated circuit 306.

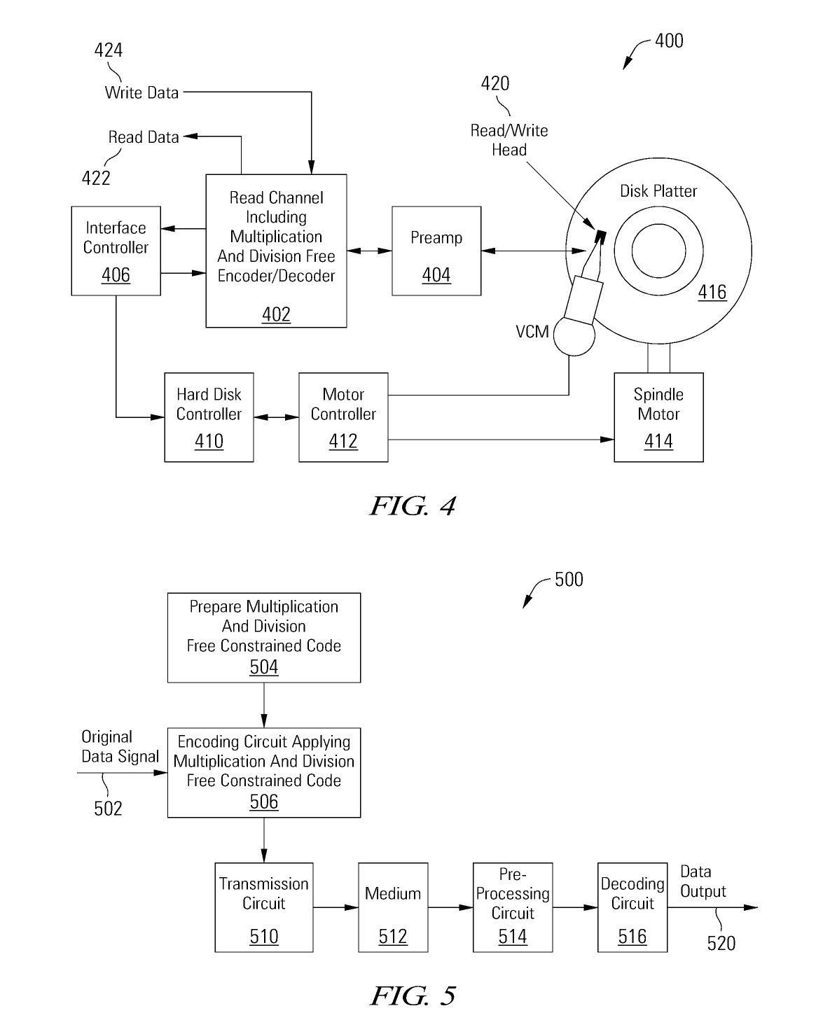

Although an encoder and decoder generated as disclosed herein are not limited to use in any particular application, they may be used in a read channel of a storage device. Turning to FIG. 4, a storage system 400 including a read channel circuit 402 having a multiplication and division free encoder and decoder is shown in accordance with some embodiments of the present inventions. Storage system 400 may be, for example, a hard disk drive. Storage system 400 also includes a preamplifier 404, an interface controller 406, a hard disk controller 410, a motor controller 412, a spindle motor 414, a disk platter 416, and a read/write head 420. Interface controller 406 controls addressing and timing of data to/from disk platter 416. The data on disk platter 416 consists of groups of magnetic signals that may be detected by read/write head assembly 420 when the assembly is properly positioned over disk platter 416. In one embodiment, disk platter 416 includes magnetic signals recorded in accordance with either a longitudinal or a perpendicular recording scheme.

In a typical read operation, read/write head assembly 420 is accurately positioned by motor controller 412 over a desired data track on disk platter 416. Motor controller 412 both positions read/write head assembly 420 in relation to disk platter 416 and drives spindle motor 414 by moving read/write head assembly to the proper data track on disk platter 416 under the direction of hard disk controller 410. Spindle motor 414 spins disk platter 416 at a determined spin rate (RPMs). Once read/write head assembly 420 is positioned adjacent the proper data track, magnetic signals representing data on disk platter 416 are sensed by read/write head assembly 420 as disk platter 416 is rotated by spindle motor 414. The sensed magnetic signals are provided as a continuous, minute analog signal representative of the magnetic data on disk platter 416. This minute analog signal is transferred from read/write head assembly 420 to read channel circuit 402 via preamplifier 404. Preamplifier 404 is operable to amplify the minute analog signals accessed from disk platter 416. In turn, read channel circuit 402 decodes and digitizes the received analog signal to recreate the information originally written to disk platter 416. This data is provided as read data 422 to a receiving circuit. As part of processing the received information, read channel circuit 402 processes the received signal using a multiplication and division free encoder and decoder. A write operation is substantially the opposite of the preceding read operation with write data 424 being provided to read channel circuit 402. This data is then encoded and written to disk platter 416. It should be noted that various functions or blocks of storage system 400 may be implemented in either software or firmware, while other functions or blocks are implemented in hardware.

Storage system 400 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such as storage system 400, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

Turning to FIG. 5, a data processing system 500 relying on a multiplication and division free encoder and decoder is shown in accordance with various embodiments of the present invention. Data processing system 500 includes an encoding circuit 506 that applies multiplication and division free encoding to an original input 502. Original input 502 may be any set of input data. For example, where data processing system 500 is a hard disk drive, original input 502 may be a data set that is destined for storage on a storage medium. In such cases, a medium 512 of data processing system 500 is a storage medium. As another example, where data processing system 500 is a communication system, original input 502 may be a data set that is destined to be transferred to a receiver via a transfer medium. Such transfer mediums may be, but are not limited to, wired or wireless transfer mediums. In such cases, a medium 512 of data processing system 500 is a transfer medium. The multiplication and division free encoder design or instructions are received from a block 504 that generates a multiplication and division free encoder and decoder as disclosed below based upon constraints to be applied in the system.

Encoding circuit 506 provides encoded data (i.e., original input encoded using the multiplication and division free encoder) to a transmission circuit 510. Transmission circuit 510 may be any circuit known in the art that is capable of transferring the received encoded data via medium 512. Thus, for example, where data processing circuit 500 is part of a hard disk drive, transmission circuit 510 may include a read/write head assembly that converts an electrical signal into a series of magnetic signals appropriate for writing to a storage medium. Alternatively, where data processing circuit 500 is part of a wireless communication system, transmission circuit 510 may include a wireless transmitter that converts an electrical signal into a radio frequency signal appropriate for transmission via a wireless transmission medium. Transmission circuit 510 provides a transmission output to medium 512.

Data processing circuit 500 includes a pre-processing circuit 514 that applies one or more analog functions to transmitted input from medium 512. Such analog functions may include, but are not limited to, amplification and filtering. Based upon the disclosure provided herein, one of ordinary skill in the art will recognize a variety of pre-processing circuitry that may be used in relation to different embodiments of the present invention. Pre-processing circuit 514 provides a pre-processed output to a decoding circuit 516. Decoding circuit 516 includes a decoder that is capable of reversing the encoding process applied by encoding circuit 506 to yield data output 520.

A multiplication and division free code for constrained systems which may be encoded and decoded using binary shift operations in place of intensive arithmetic operations such as multiplication and division is generated using directed graphs, or digraphs, which characterize the system constraints. The constraints may, for example, prevent undesirable patterns for a particular storage or transmission medium, such as long runs of 0's or long runs of transitions. A labeled digraph DG=(V, A, L) consists of a finite set of states V=V_{DG}, a finite set of arcs A=A_{DG} where each arc e has an initial state σ_{DG}(e)εV_{DG} and a terminal state τ_{DG}(e)εV_{DG}, and an arc labeling L=L_{DG}: A→H where H is a finite alphabet. A set of all finite sequences obtained from reading the labels of paths in a labeled digraph DG is called a constrained system, S. DG presents S, denoted by S=S (DG).

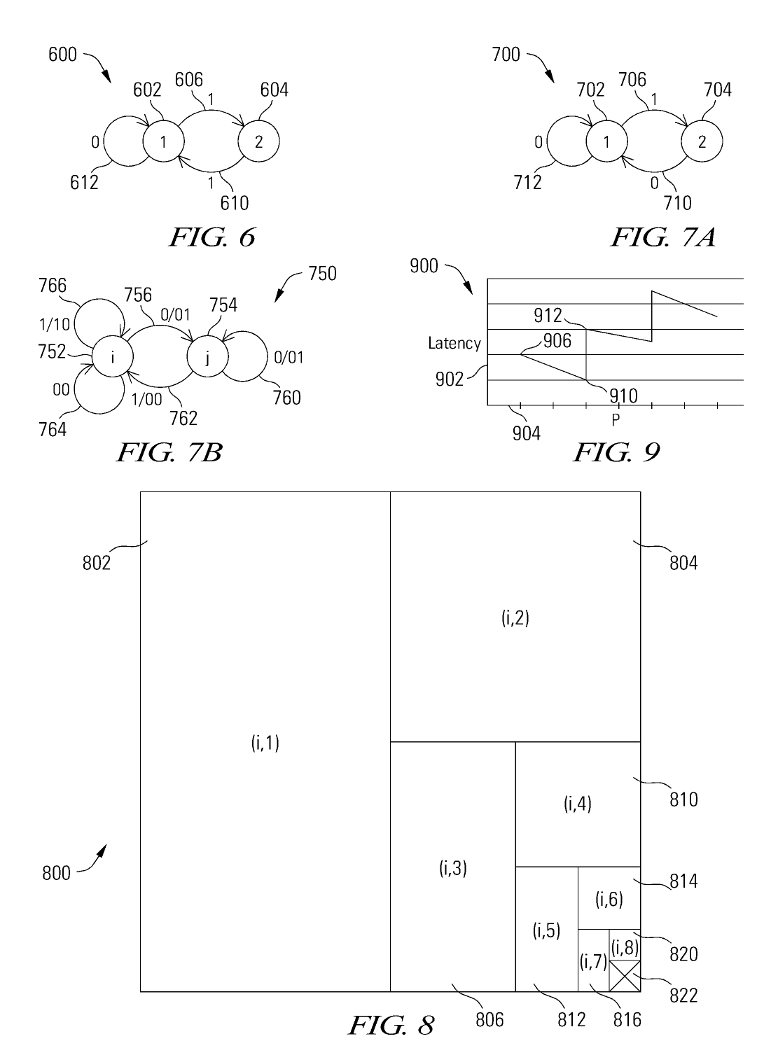

Turning to FIG. 6, a simple labeled digraph (DG) 600 is shown having two states, state 1 602 and state 2 604, with paths or edges entering and exiting the states 602 and 604 that are labeled to indicate the output value when that path is taken. From state 1 602 a self-loop 612 is labeled 0 to indicate that a 0 is output when the system transitions from state 1 602 back to state 1 602 in one step. An arc 606 from state 1 602 to state 2 604 is labeled 1, indicating that a 1 is output when the system transitions from state 1 602 to state 2 604. Arc 610 from state 2 604 to state 1 602 is labeled 1. Given a labeled DG 600, the output can be determined by taking the paths from state to state. For example, starting from state 1 602 and taking self-loop 612, arc 606, arc 610 and self-loop 612 yields an output of 0110. In this labeled DG 600, 1's are produced in even numbers. When designing a code for a constrained system, a labeled DG can be produced that characterizes the constraint set.

Constraint sequences can be mapped to sequences generated by a labeled DG using symbolic dynamics. In this process, a connectivity matrix is generated for the labeled DG. For the labeled DG 600 of FIG. 6, the connectivity matrix is:

$$[ \begin{matrix}1 & 1 \\ 1 & 0\end{matrix} ]$$

where element 1,1 represents the connection 612 from state 1 602 to state 1 602, element 1,2 represents the connection 606 from state 1 602 to state 2 604, element 2,1 represents the connection 610 from state 2 604 to state 1 602, and the 0 in element 2,2 represents the lack of a connection from state 2 604 to state 2 604.

The highest rate code that can be designed from a labeled DG can be computed as log(λ), where λ is the largest real and positive eigenvalue of connectivity matrix. For an eigenvalue λ, there is a vector x that satisfies the equation A*x=λ*x, where A is the connectivity matrix, x is a vector, and λ is the eigenvalue number. If the matrix A is non-negative and real, meaning that there are no complex numbers in the connectivity matrix, and that it contains 0's or positive numbers, then λ is also a real, non-negative number that allows the computation of the highest rate code. If the input block length of the encoder is denoted L, and the output block length is denoted N, where N>L, the encoder can be designed to map the L input bits to N output bits in an invertible manner. Given L input bits, there are 2^{L} input patterns to be mapped to outputs. Each of the N blocks are referred to as codewords in a codeword space, generally a subset of all the possible output patterns. The resulting encoder has a rate L/N, and the higher the rate, the greater the efficiency of the encoding.

The labeled DG characterizes the constraints and can be used to calculate the code rate, but does not define the mapping between inputs and outputs. The mapping can be performed using a power of a labeled DG. Turning to FIGS. 7A and 7B, another labeled DG 700 and its 2^{nd} power DG 750 are shown to illustrate a possible mapping between input and output patterns. Labeled DG 700 includes state 1 702 and state 2 704, with arc 706 from state 1 702 to state 2 704 labeled 1, arc 710 from state 2 704 to state 1 702 labeled 0, and self-loop 712 from state 1 702 labeled 0. This labeled DG 700 will not generate two 1's in sequence. If 1's represent transitions, then no two transitions are adjacent.

To map input bits to output bits, a DG may be taken to a power based on the rate and on the number of output bits for each input bit. For example, in a ½ rate code, two output bits are produced for every input bit, and the 2^{nd} power 750 of the DG 700 may be used for the mapping. The 2^{nd} power DG 750 of the DG 700 has the same number of states, state i 752 and state j 754. There is an arc from state i 752 to state j 754 in the 2^{nd} power DG 750 if there is a path of length two from state 1 702 to state 2 704 in DG 700. Because state 1 702 to state 2 704 in DG 700 can be reached in two steps on arcs 712 and 706, with labels 0 and 1, 2^{nd} power DG 750 includes an arc 756 labeled 01 from state i 752 to state j 754. Based on the two-step paths in DG 700, 2^{nd} power DG 750 also includes self-loop 760 labeled 01 from state j 754, arc 762 labeled 00 from state j 754 to state i 752, self-loop 764 labeled 00 from state i 752 and self-loop 766 labeled 10 from state i 752. These labels represent the outputs for each state transition from state i 752 and state j 754.

Input bits can be mapped to the paths in 2^{nd} power DG 750 in any suitable manner, including in a somewhat arbitrary manner. Based upon the disclosure provided herein, one of ordinary skill in the art will recognize a variety of mapping techniques that may be used to characterize a constrained code from a digraph. Each incoming bit is assigned to a path in 2^{nd} power DG 750, for example assigning incoming bit 1 when received in state i 752 to self-loop 766, so that when a 1 is received in that state, a 10 is yielded at the output. (The notation 1/10 is used in the label for self-loop 766, with the incoming value before the slash and the outgoing value after the slash.) Incoming bit 0 is assigned when received in state i 752 to arc 756 so that when a 1 is received in state i 752, a 01 is output. At this point, with incoming bit values 0 and 1 having been mapped for state i 752, self-loop 764 is not needed. Incoming bit values 0 and 1 when received in state j 754 are assigned to self-loop 760 and arc 762, respectively.

The 2^{nd} power DG 750 when labeled defines the encoder, because it describes fully how input bits are mapped to output bits at a rate 1:2, or code rate ½, in an invertible manner that satisfies the constraint of preventing consecutive 1's.

In this simple example, each state 752 and 754 had sufficient outgoing edges to map each possible input bit. However, given a DG and its powers, this is often not the case. For example, to design a ⅔ code rate encoder based on labeled DG 700, the labeled DG 700 is taken to the 3^{rd} power, yielding connectivity matrix

$$[ \begin{matrix}2 & 1 \\ 1 & 1\end{matrix} ]$$

for the 2^{nd} power and connectivity matrix

$$[ \begin{matrix}3 & 2 \\ 2 & 1\end{matrix} ]$$

for the 3rd power. This indicates that state 1 in the 3^{rd} power DG will have 5 outgoing edges and state 2 in the 3^{rd} power DG will have 3 outgoing edges. Given two input bits in the ⅔ code rate encoder, four outgoing edges are needed from each state, and state 2 has too few outgoing edges, preventing the simple mapping of input to output bits in a power of the original DG as in FIGS. 7A and 7B.

State splitting may be used to manipulate the DG to produce another DG that generates the same sequences, but for which every state has at least the necessary number of outgoing edges so that the encoder can be designed by arbitrarily assigning input bits to outgoing edges. State splitting redistributes outgoing edges, taking them from states with an excess and redistributing them to states with insufficient edges until each state has at least the minimum number of outgoing edges to achieve the desired code rate. In general, because λ can be any real number, the x vector may also be a non-integral real number. Given a log(λ) that is at least slightly larger than the desired code rate, a non-negative integer approximate eigenvector can be found that satisfies the equation A*x≧λ*x, where x is a non-negative integer that enables the use of a state splitting algorithm.

In general, state splitting is performed by identifying the largest coordinates of vector x and splitting the corresponding state into a number of smaller states. The outgoing edges from the original state are partitioned into two or more subsets, each of which are assigned to a new state. Each of the new smaller states have the same input as the original state. The resulting digraph thus has more states than the original digraph, with a new approximate eigenvector. In some embodiments, the end result of the state splitting operation is an approximate eigenvector in which every state has a coordinate or weight of 1 or 0, with the number of states equaling the sum of the coordinates of vector x.

If the constraints result in an approximate eigenvector where the sum of the coordinates is a very large number, the resulting encoder can be very complicated, using many multipliers and dividers, which greatly increases hardware complexity. Thus, even when state splitting provides sufficient edges from each state to map input bits to output bits at the desired code rate, traditional mappings may require arithmetic divisions and multiplications for large integers in the encoder. To avoid this, a representation is found for a subset DG* of digraph DG that supports codes that require no multiplication or division, except by powers of 2 that can be performed with binary shift operations.

To identify the subset DG*, the approximate eigenvector AE is generated for digraph DG according to Equation 1:

T(DG)*AE(DG)′≧2^{L}*AE(DG)′ (Eq 1)

where T(DG) is the connectivity matrix for digraph DG and AE(DG)′ is an approximate Eigenvector in row vector form corresponding to digraph DG, transposed to yield a column vector. The left side of Equation 1 is a matrix multiplied by a column vector, resulting in a column vector The right side of Equation 1 is a column vector.

If possible, an approximate eigenvector AE is found that satisfies Equation 2:

T(DG)*AE(DG)′>P+2^{L}*AE(DG)′ (Eq 2)

where P is a real number. Where the largest eigenvector is already 2^{L}, the inequality cannot be satisfied when a real positive number P is added, however, this is uncommon. Because log(λ) is most often a real irrational number, there will be a rational approximation that permits the addition of P.

An approximation AE* to approximate eigenvector AE is identified that satisfies Equation 3:

T(DG)*AE*(DG)′>P*+2^{L}*AE*(DG)′ (Eq 3)

such that the number of 1's in the binary representation of AE*(i) coordinates does not exceed K for all i states, where K is the maximum number of ones in the binary representation of the coordinates of the approximate eigenvector used in the first stage of the state splitting operation. The coordinates of AE* are integers which, when represented in binary, do not have more than K 1's. P* may be smaller than P due to the approximation performed in finding AE*.

State splitting is applied to digraph DG in two stages. In the first stage, digraph DG is split using AE* such that the approximate eigenvector AE1 of resulting digraph DG1 has an Eigenvector coordinate that is a power of 2. More specifically, each state i in digraph DG is split into at most K states having AE1(state(i,j))=λ(i,j), where λ(i,j) is a power of 2. K is equal to 8 in some embodiments but is not limited to any particular value. As shown in FIG. 8, in the embodiments in which K=8, state i 800 is split into at most K states (i,1) 802, (i,2) 804, (i,3) 806, (i,4) 810, (i,5) 812, (i,6) 814, (i,7) 816, (i,8) 820. This is performed by partitioning the outgoing edges of state i 800, assigning one group in the partition to new state (i,1) 802 which takes a subset of the outgoing edges from original state i 800. From the remainder of the outgoing edges from original state i 800, another state (i,2) 804 takes another subset of the remaining outgoing edges not already taken by state (i,1) 802. When generate state (i,1) 802, enough edges are taken so that the weight of that state, or the eigenvector value of that state, is a power of 2. When generating state (i,2) 804, enough edges are taken so that its weight is a power of 2. In general, after the stage 1 state splitting operation, there may be a few edges 822 left which are discarded and not used in the encoder.

The value for K may be established by selecting a value, splitting every state of digraph DG to up to that selected number of states, and finding the largest eigenvector of the resulting digraph, and if it is large enough to satisfy Equation 4, K is large enough, otherwise, K is increased and the process is repeated. Again, in the first stage state splitting digraph DG is split using AE* such that the approximate eigenvector AE1 of resulting digraph DG1 has an Eigenvector coordinate that is a power of 2:

T1(DG1)*AE1*(DG1)′≧P1*+2^{L}*AE1*(DG1)′ (Eq 4)

where T1 is the connectivity matrix associated with DG1.

More specifically, the first stage state splitting is performed starting with AE*(i)=λ(i). Letting b denote the base 2 representation of λ(i), b=[b(k) b(k−1) b(k−2) . . . b(2) b(1) b(0)], where b's are binary. The location of 1's in b are specified by j's, where j1>j2> . . . >jq for q≦K. States are split from state i with the following weights or AE1 values:

$$For state ( i , 1 ) , AE 1 ( i , 1 ) = {2}^{j 1}$$

$$For state ( i , 2 ) , AE 1 ( i , 2 ) = {2}^{j 2}$$

$$For state ( i , 3 ) , AE 1 ( i , 3 ) = {2}^{j 3}$$

$$…$$

$$For state ( i , q ) , AE 1 ( i , q ) = {2}^{jq}$$

In the second stage of state splitting, the resulting digraph DG1 may be split using AE1 in any suitable manner, such as with a traditional state splitting algorithm, to yield digraph DG2 with approximate eigenvector AE2, where the weights or coordinates of AE2 are all 0's or 1's. Based upon the disclosure provided herein, one of ordinary skill in the art will recognize a variety of state splitting algorithms that may be used in relation to different embodiments of the present inventions to split DG1 using AE1 to yield digraph DG2 with approximate eigenvector AE2, where the weights or coordinates of AE2 are all 0's or 1's.

Because the second stage of state splitting begins with an approximate eigenvector AE1 in which all coordinates are powers of 2, multiplication and division operations needed to implement the code in the resulting encoder and decoder will be performed on integers that are powers of 2. This allows binary shift operations to be used rather than multiplication and division operations, greatly simplifying the encoder and decoder.

The encoder and decoder may then be generated in any suitable manner based on DG2, for example using the mapping of inputs to outputs disclosed above with respect to FIGS. 7A and 7B. Based upon the disclosure provided herein, one of ordinary skill in the art will recognize a variety of techniques that may be used in relation to different embodiments of the present inventions to produce an encoder and decoder based on digraph DG2.

In general, satisfying Equation 3 is straightforward if P* is large enough, and a large P value promotes a large P*. If Equation 3 is satisfied with K=1, then AE1 can be considered to be another approximate eigenvector for DG. Because Equation 2 uses a greater than inequality, the last step of state splitting will have extra edges that are not needed for encoding, due to the approximation of AE in AE*. Each time edges are discarded in a state splitting operation, there is a danger that too many edges will be discarded and there will be insufficient edges remaining to result in the desired code rate. However, K can be increased to a sufficient level to prevent this outcome, and complexity in the implementation of the encoder and decoder due to K is substantially linear. The value P is a measure of the cushion in the extra edges, and if it gets too small as edges are discarded the design will fail. If an AE* is found with a large P*, there will be a relatively larger number of extra edges that can be discarded during the design process, and this can enable the use of a smaller K.

Turning to FIG. 9, the relationship between latency and P is not linear. In graph 900, the Y axis 902 corresponds to latency and the X axis 904 corresponds to the value of P. Notably, as P increases from one point 906 to another point 910, the latency can actually decrease as P increases until it reaches the point 910 at which it jumps to another level 912. Thus, although in general a larger P promotes a larger P* which is desirable, it also increases AE. Traditionally, constrained system code design has attempted to minimize AE in order to decrease complexity. However, by freeing the encoder and decoder from multipliers and dividers, the system is simplified even though AE is increased, and if AE is not pushed past the threshold at which latency jumps, latency may not be adversely affected by the larger AE.

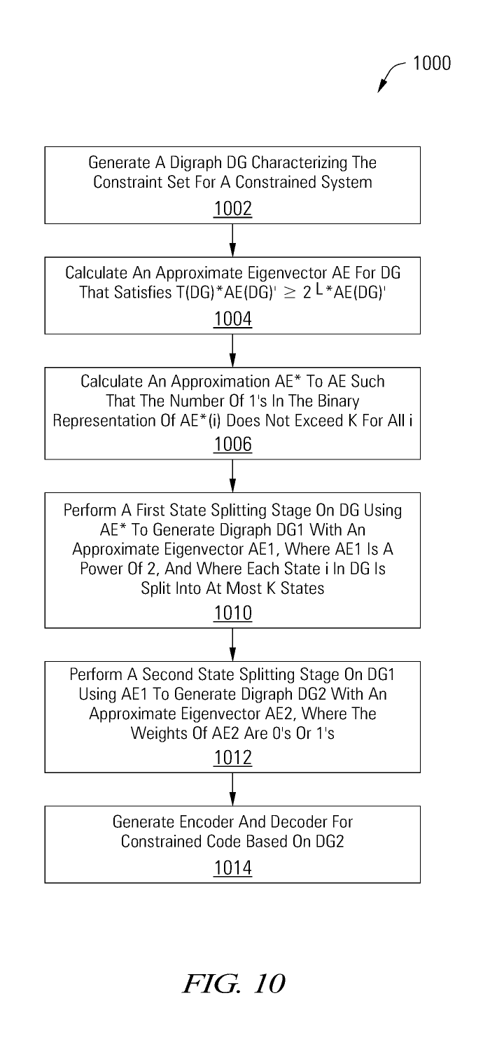

Turning to FIG. 10, a flow diagram 1000 depicts a method for generating a constrained systems endec in accordance with various embodiments of the present inventions. Following flow diagram 1000, a digraph DG is generated characterizing the constraint set for a constrained system. (Block 1002) An approximate eigenvector AE is calculated for DG that satisfies Equation 1. (Block 1004) An approximation AE* is calculated for AE such that the number of 1's in the binary representation of AE*(i) does not exceed K for all I, where K is the maximum number of states into which each state in the digraph DG will be split in a first stage of state splitting. (Block 1006) A first state splitting stage is performed on DG using AE* to generate digraph DG1 with an approximate eigenvector AE1, where AE1 is a power of 2, and where each state i in DG is split into at most K states. (Block 1010) A second state splitting stage is performed on DG1 using AE1 to generate digraph DG2 with an approximate eigenvector AE2, where the weights of AE2 are 0's or 1's. (Block 1012) An encoder and decoder are then generated for the constrained code based on DG2. (Block 1014)

In one embodiment of the method for generating a constrained systems endec, DG has 67 states such that the connectivity matrix is a 67×67 integer matrix and each arc is labeled by a 36 bit binary sequence in order to design a rate 34/36 code based on DG. An approximate integer eigenvector AE is set forth in Table 1:

TABLE 1

| AE | State |
|---|---|
| 1 | 8192 |
| 2 | 7600 |
| 3 | 6445 |
| 4 | 4246 |
| 5 | 7365 |
| 6 | 6243 |
| 7 | 4113 |
| 8 | 7626 |
| 9 | 6745 |
| 10 | 5711 |
| 11 | 3764 |
| 12 | 6444 |
| 13 | 5576 |
| 14 | 4715 |
| 15 | 3108 |
| 16 | 5119 |
| 17 | 4354 |
| 18 | 3679 |
| 19 | 2425 |
| 20 | 3872 |
| 21 | 3247 |
| 22 | 2741 |
| 23 | 1808 |
| 24 | 2809 |
| 25 | 2325 |
| 26 | 1961 |
| 27 | 1293 |
| 28 | 1959 |
| 29 | 1601 |
| 30 | 1349 |
| 31 | 890 |
| 32 | 1313 |
| 33 | 1058 |
| 34 | 891 |
| 35 | 588 |
| 36 | 842 |
| 37 | 668 |
| 38 | 562 |
| 39 | 371 |
| 40 | 513 |
| 41 | 399 |
| 42 | 335 |
| 43 | 221 |
| 44 | 291 |
| 45 | 220 |
| 46 | 185 |
| 47 | 122 |
| 48 | 149 |
| 49 | 107 |
| 50 | 90 |
| 51 | 59 |
| 52 | 63 |
| 53 | 41 |
| 54 | 34 |
| 55 | 22 |
| 56 | 10 |
| 57 | 5 |
| 58 | 4 |
| 59 | 3 |
| 60 | 1 |
| 61 | 0 |
| 62 | 0 |
| 63 | 0 |
| 64 | 0 |
| 65 | 0 |
| 66 | 0 |
| 67 | 0 |

Referring to Equation 2, the value of P for the AE in Table 1 is 0.0249, which is too small to result in the desired code rate. One way to increase P is the following:

Starting from Equation 2: T(DG)*AE(DG)′>P+2^{L}*AE(DG)′

1) let q=(T(DG)*AE(DG)′−2^{L}*AE(DG)′)/2^{L}

2) find a location j in q such that q(j)>1

3) modify AE(DG,j)=AE(DG,j)+1

Repeat step 1 until minimum of q is large enough. Then P equals 2^{L} times the minimum of q.

By increasing P to 67 to provide a larger cushion in the number of edges that can be discarded during the design process, the approximate eigenvector AE is changed to that set forth in Table 2:

TABLE 2

| state | AE |
|---|---|
| 1 | 2451996317 |
| 2 | 2275217668 |
| 3 | 1929560641 |
| 4 | 1271075940 |
| 5 | 2206213663 |
| 6 | 1870112853 |
| 7 | 1232076509 |
| 8 | 2285987210 |
| 9 | 2023893199 |
| 10 | 1713866024 |
| 11 | 1129421828 |
| 12 | 1938025796 |
| 13 | 1679338520 |
| 14 | 1420283677 |
| 15 | 936243748 |
| 16 | 1546591233 |
| 17 | 1317966836 |
| 18 | 1113557385 |
| 19 | 734226072 |
| 20 | 1176823872 |
| 21 | 989084852 |
| 22 | 834988412 |
| 23 | 550661650 |
| 24 | 859792142 |
| 25 | 713640056 |
| 26 | 601997386 |
| 27 | 397080946 |
| 28 | 604891610 |
| 29 | 495960239 |
| 30 | 418055325 |
| 31 | 275802106 |
| 32 | 409743604 |
| 33 | 331644382 |
| 34 | 279324049 |
| 35 | 184313465 |
| 36 | 266391259 |
| 37 | 212456077 |
| 38 | 178771148 |
| 39 | 117989873 |
| 40 | 165010572 |
| 41 | 129188455 |
| 42 | 108575564 |
| 43 | 71681203 |
| 44 | 95964785 |
| 45 | 73199368 |
| 46 | 61413861 |
| 47 | 40562173 |
| 48 | 50800594 |
| 49 | 37083667 |
| 50 | 31018783 |
| 51 | 20502176 |
| 52 | 22621787 |
| 53 | 15130068 |
| 54 | 12580172 |
| 55 | 8325875 |
| 56 | 4675379 |
| 57 | 2700746 |
| 58 | 2227018 |
| 59 | 1475850 |
| 60 | 1035101 |
| 61 | 570213 |
| 62 | 469040 |
| 63 | 310948 |
| 64 | 196791 |
| 65 | 99345 |
| 66 | 81185 |
| 67 | 53884 |

In this case, the DG and corresponding approximate eigenvector AE does not have an immediate approximate eigenvector AE* for which coordinates are a power of 2 and satisfying Equation 1 with N=34. Therefore, the first stage state splitting is performed. Although in this case any integers greater than or equal to 7 are candidates for K, and K=8 is selected for ease in state splitting DG to yield DG1. The resulting approximate eigenvectors AE* and AE1 are characterized as follows:

$${AE}^{*} ( i ) = {\sum }_{{j = 1}_{JB ( i , j ) \neq 0}}^{j = 8} {2}^{35 - JB ( i , j )}$$

$$AE 1 ( i , j ) = {2}^{35 - JB ( i , j )}$$

for 1≦i≦67, and 1≦j≦8. Notably, if JB(i,j)=0, there is no state (i,j).

JB(i,j) is given in Table 3, specifying the position of the 1's in AE*(i). Again, the number of 1's in the binary representation of AE*(i) does not exceed K for all i states, in this case in all 8 states.

TABLE 3

| i | j = 1 | j = 2 | j = 3 | j = 4 | j = 5 | j = 6 | j = 7 | j = 8 |
|---|---|---|---|---|---|---|---|---|
| 1 | 1 | 4 | 7 | 11 | 14 | 15 | 18 | 19 |
| 2 | 1 | 6 | 7 | 8 | 9 | 12 | 13 | 14 |
| 3 | 2 | 3 | 4 | 7 | 8 | 15 | 17 | 18 |
| 4 | 2 | 5 | 7 | 8 | 9 | 10 | 15 | 16 |
| 5 | 1 | 7 | 8 | 9 | 19 | 22 | 23 | 28 |
| 6 | 2 | 3 | 5 | 6 | 7 | 8 | 10 | 11 |
| 7 | 2 | 5 | 8 | 10 | 11 | 13 | 14 | 15 |
| 8 | 1 | 5 | 10 | 16 | 18 | 19 | 22 | 24 |
| 9 | 2 | 3 | 4 | 5 | 9 | 11 | 15 | 19 |
| 10 | 2 | 3 | 6 | 7 | 11 | 14 | 15 | 16 |
| 11 | 2 | 7 | 8 | 10 | 12 | 16 | 17 | 20 |
| 12 | 2 | 3 | 4 | 7 | 8 | 9 | 15 | 16 |
| 13 | 2 | 3 | 6 | 12 | 13 | 17 | 19 | 21 |
| 14 | 2 | 4 | 6 | 9 | 11 | 14 | 15 | 16 |
| 15 | 3 | 4 | 6 | 7 | 8 | 9 | 10 | 13 |
| 16 | 2 | 4 | 5 | 6 | 11 | 13 | 14 | 15 |
| 17 | 2 | 5 | 6 | 7 | 9 | 13 | 14 | 15 |
| 18 | 2 | 7 | 10 | 12 | 13 | 14 | 15 | 16 |
| 19 | 3 | 5 | 7 | 8 | 9 | 10 | 15 | 16 |
| 20 | 2 | 6 | 7 | 11 | 14 | 17 | 18 | 19 |
| 21 | 3 | 4 | 5 | 7 | 9 | 10 | 11 | 12 |
| 22 | 3 | 4 | 8 | 9 | 10 | 14 | 17 | 18 |
| 23 | 3 | 9 | 10 | 12 | 15 | 18 | 19 | 21 |
| 24 | 3 | 4 | 7 | 8 | 11 | 12 | 13 | 14 |
| 25 | 3 | 5 | 7 | 9 | 13 | 16 | 18 | 21 |
| 26 | 3 | 7 | 8 | 9 | 10 | 11 | 16 | 17 |
| 27 | 4 | 6 | 7 | 8 | 9 | 11 | 13 | 15 |
| 28 | 3 | 6 | 13 | 14 | 16 | 17 | 18 | 19 |
| 29 | 4 | 5 | 6 | 8 | 9 | 13 | 14 | 15 |
| 30 | 4 | 5 | 9 | 10 | 11 | 13 | 15 | 16 |
| 31 | 4 | 10 | 11 | 12 | 18 | 19 | 22 | 23 |
| 32 | 4 | 5 | 10 | 11 | 13 | 14 | 19 | 20 |
| 33 | 4 | 7 | 8 | 9 | 10 | 14 | 18 | 19 |
| 34 | 4 | 9 | 11 | 14 | 15 | 19 | 22 | 24 |
| 35 | 5 | 7 | 9 | 10 | 11 | 12 | 13 | 14 |
| 36 | 5 | 6 | 7 | 8 | 9 | 10 | 11 | 17 |
| 37 | 5 | 6 | 9 | 11 | 13 | 16 | 17 | 18 |
| 38 | 5 | 7 | 9 | 11 | 14 | 15 | 16 | 17 |
| 39 | 6 | 7 | 8 | 13 | 18 | 19 | 24 | 25 |
| 40 | 5 | 8 | 9 | 10 | 12 | 14 | 16 | 17 |
| 41 | 6 | 7 | 8 | 9 | 11 | 12 | 15 | 16 |
| 42 | 6 | 7 | 10 | 11 | 12 | 13 | 17 | 19 |
| 43 | 6 | 10 | 14 | 16 | 17 | 18 | 22 | 25 |
| 44 | 6 | 8 | 9 | 11 | 12 | 13 | 18 | 21 |
| 45 | 6 | 10 | 12 | 13 | 14 | 17 | 18 | 19 |
| 46 | 7 | 8 | 9 | 11 | 13 | 16 | 20 | 21 |
| 47 | 7 | 10 | 11 | 13 | 15 | 17 | 18 | 19 |
| 48 | 7 | 8 | 14 | 15 | 16 | 19 | 22 | 23 |
| 49 | 7 | 11 | 12 | 14 | 16 | 17 | 18 | 20 |
| 50 | 8 | 9 | 10 | 12 | 13 | 16 | 18 | 21 |
| 51 | 8 | 11 | 12 | 13 | 17 | 18 | 20 | 22 |
| 52 | 8 | 10 | 12 | 13 | 16 | 19 | 21 | 22 |
| 53 | 9 | 10 | 11 | 14 | 15 | 17 | 18 | 20 |
| 54 | 9 | 11 | 12 | 13 | 14 | 15 | 16 | 17 |
| 55 | 10 | 11 | 12 | 13 | 14 | 15 | 16 | 21 |
| 56 | 10 | 14 | 15 | 16 | 18 | 20 | 22 | 23 |
| 57 | 11 | 13 | 16 | 19 | 20 | 22 | 24 | 25 |
| 58 | 11 | 16 | 17 | 18 | 19 | 20 | 21 | 23 |
| 59 | 12 | 14 | 15 | 17 | 22 | 24 | 29 | 31 |
| 60 | 13 | 14 | 15 | 16 | 17 | 18 | 21 | 23 |
| 61 | 13 | 17 | 19 | 20 | 23 | 24 | 26 | 27 |
| 62 | 14 | 15 | 16 | 19 | 21 | 27 | 28 | 0 |
| 63 | 14 | 17 | 19 | 20 | 21 | 22 | 23 | 25 |
| 64 | 15 | 16 | 25 | 27 | 28 | 30 | 31 | 32 |
| 65 | 16 | 17 | 22 | 28 | 32 | 0 | 0 | 0 |
| 66 | 16 | 19 | 20 | 21 | 22 | 24 | 27 | 32 |
| 67 | 17 | 18 | 20 | 23 | 26 | 27 | 28 | 29 |

The location of the 1's in AE*(i) is specified by 2̂35−j. Thus, for state i=1, j=1, Table 3 indicates that the first 1 in state 1 is at 2̂(35−1), or 2̂34. The second 1 in state 1 is at position 2̂(35−4) or 2̂31.

The digraph DG is then split using AE* in a second stage state splitting operation as disclosed above to yield DG1. If P* in Equation 3 is greater than or equal to K, the splitting from DG to DG1 can be performed in one round of state splitting. Thus, because P≧8, the splitting from DG to DG1 can be performed in one round of state splitting, although it is not necessary that this condition be satisfied.

The desired encoder/decoder is then generated by applying the second stage of state splitting from DG1 to DG2, followed by generating the encoder/decoder based on DG2. The resulting 34/36 code can be applied in the encoder and decoder using binary shift operations rather than multiplication and division operations, greatly simplifying the hardware design or computer execution of the encoder and decoder.

It should be noted that the various blocks discussed in the above application may be implemented in integrated circuits along with other functionality. Such integrated circuits may include all of the functions of a given block, system or circuit, or only a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the present invention provides novel apparatuses and methods for encoding and decoding data for constrained systems with reduced or eliminated need for hardware and time intensive arithmetic operations such as multiplication and division. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A method of generating an encoder comprising:
generating a first directed graph characterizing a constraint set for a constrained system;
calculating a first approximate eigenvector for the first directed graph;
calculating a second approximate eigenvector as an approximation of the first approximate eigenvector;
performing a first state splitting operation on the first directed graph using the second approximate eigenvector to yield a second directed graph with a third approximate eigenvector;
performing a second state splitting operation on the second directed graph with the third approximate eigenvector to yield a third directed graph with a fourth approximate eigenvector; and
generating the encoder based on the third directed graph.

2. The method of claim 1, wherein a connectivity matrix for the first directed graph multiplied by the first approximate eigenvector is at least equal to the first approximate eigenvector multiplied by a power of 2.

3. The method of claim 1, wherein a number of ones in a binary representation of the second approximate eigenvector does not exceed a maximum number of states into which the first directed graph is split in the first state splitting operation for all states in the second directed graph.

4. The method of claim 3, further comprising upper bounding to a number K a number of states produced from each state during the first state splitting operation.

5. The method of claim 4, wherein the number K is selected from a group consisting of: seven and eight.

6. The method of claim 3, further comprising selecting the maximum number of states in order that a desired code rate can be achieved when generating the encoder after discarding at least one edge in the first directed graph during the first state splitting operation.

7. The method of claim 1, wherein the second approximate eigenvector comprises coordinates that are each a power of 2.

8. The method of claim 1, wherein the fourth approximate eigenvector comprises coordinates with values of zero or one.

9. The method of claim 1, wherein a connectivity matrix for the first directed graph multiplied by the second approximate eigenvector is greater than the second approximate eigenvector multiplied by a power of 2 plus a real number.

10. The method of claim 9, further comprising selecting a value of the real number in order that a desired code rate can be achieved when generating the encoder after discarding at least one edge in the first directed graph during the first state splitting operation.

11. The method of claim 1, wherein a connectivity matrix for the second directed graph multiplied by the third approximate eigenvector is at least equal to the third approximate eigenvector multiplied by a power of 2 plus a real number.

12. The method of claim 1, wherein the method is at least in part performed by a processor executing instructions.

13. The method of claim 1, wherein the method is at least in part performed by an integrated circuit.

14. The method of claim 1, further comprising including the encoder in a storage system to encode data prior to storage in the storage system.

15. A system for generating an encoder comprising:
a tangible computer readable medium, the computer readable medium including instructions executable by a processor to:
generate a first directed graph characterizing a constraint set for a constrained system;
calculate a first approximate eigenvector for the first directed graph;
calculate a second approximate eigenvector as an approximation of the first approximate eigenvector;
perform a first state splitting operation on the first directed graph using the second approximate eigenvector to yield a second directed graph with a third approximate eigenvector;
perform a second state splitting operation on the second directed graph with the third approximate eigenvector to yield a third directed graph with a fourth approximate eigenvector; and
generate the encoder based on the third directed graph.

16. The system of claim 15, wherein a number of ones in a binary representation of the second approximate eigenvector does not exceed a maximum number of states into which the first directed graph is split in the first state splitting operation for all states in the second directed graph.

17. The system of claim 15, wherein encoder is operable to generate encoded data that complies with at least one pattern constraint, and wherein the encoder performs no division operations other than divisions by a power of two, and no multiplication operations other than multiplications by a power of two.

18. The system of claim 15, wherein a connectivity matrix for the first directed graph multiplied by the first approximate eigenvector is at least equal to the first approximate eigenvector multiplied by a power of 2.

19. The system of claim 15, wherein the second approximate eigenvector comprises coordinates that are each a power of 2.

20. The system of claim 15, wherein the fourth approximate eigenvector comprises coordinates with values of zero or one.

21. A storage system comprising:
a storage medium maintaining a data set;
a read/write head assembly operable to write the data set to the storage medium and to read the data set from the storage medium;
an encoder operable to encode the data set to yield encoded data before it is written to the storage medium, wherein the encoded data complies with at least one pattern constraint, and wherein the encoder performs no division operations other than divisions by a power of two, and no multiplication operations other than multiplications by a power of two; and
a decoder operable to decode the encoded data set to yield the data set after it is read from the storage medium.

22. The storage system of claim 21, wherein the encoder is implemented as an integrated circuit.
